(19) United States
(12) Patent Application Publication
(10) Pub. No.: US 2025/0079216 A1
(43) Pub. Date: Mar. 6, 2025

(54) SUBSTRATE HOLDER, SUBSTRATE PROCESSING APPARATUS, AND SUBSTRATE TRANSFER METHOD

(71) Applicant: Tokyo Electron Limited, Tokyo (JP)

(72) Inventors: Keisuke KONDOH, Nirasaki City (JP); Tomonori IWASAKI, Nirasaki City (JP)

(21) Appl. No.: 18/951,828

(22) Filed: Nov. 19, 2024

Related U.S. Application Data
(63) Continuation of application No. PCT/JP2023/017711, filed on May 11, 2023.

(30) Foreign Application Priority Data
May 24, 2022 (JP) 2022-084440

(51) Int. Cl. H01L 21/677; B25J 19/02; H01L 21/67; H01L 21/683

(52) U.S. Cl. CPC H01L 21/67712; H01L 21/67242; H01L 21/6838; B25J 19/02

(57) ABSTRACT

A substrate holder for receiving a substrate from a transfer arm and holding the substrate, includes: a stage configured to be raised and lowered in a vertical direction and configured to place the substrate thereon; a measurer configured to measure at least one of a weight, a pressure, and a displacement of the stage; and a controller configured to predict a state of the transfer arm based on measurement results of the measurer.

### CROSS-REFERENCE TO RELATED APPLICATIONS

This application is a bypass continuation application of international application No. PCT/JP2023/017711 having an international filing date of May 11, 2023 and designating the United States, the international application being based upon and claiming the benefit of priority from Japanese Patent Application No. 2022-084440, filed on May 24, 2022, the entire contents of which are incorporated herein by references.

### TECHNICAL FIELD

The present disclosure relates to a substrate holder, a substrate processing apparatus, and a substrate transfer method.

### BACKGROUND

Patent Document discloses a substrate transfer device which transfers a substrate by a vacuum-suction. The substrate transfer device includes a flange portion, a plurality of pads which hold the substrate, and a hand which detachably fixes the plurality of pads.

### PRIOR ART DOCUMENT

### Patent Document

Patent Document 1: Japanese Laid-Open Patent Publication No. 2015-103696

### SUMMARY

According to another embodiment of the present disclosure, a substrate holder for receiving a substrate from a transfer arm and holding the substrate, includes: a stage configured to be raised and lowered in a vertical direction and configured to place the substrate thereon; a measurer configured to measure at least one of a weight, a pressure, and a displacement of the stage; and a controller configured to predict a state of the transfer arm based on measurement results of the measurer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing an outline of a configuration of a wafer processing apparatus according to the present embodiment.

FIG. 2 is a perspective view showing an outline of a configuration of a transfer arm.

FIG. 3 is a perspective view showing an outline of a configuration of a holding pad.

FIG. 4 is a perspective view showing an outline of a configuration of a wafer holder.

FIG. 5 is an explanatory diagram showing how a wafer is held by the wafer holder.

FIG. 6 is a perspective view showing an outline of a configuration of a force gauge.

FIGS. 7A to 7C are explanatory diagrams showing how a wafer is transferred from the transfer arm to the wafer holder.

FIG. 8 is an explanatory diagram showing a time-dependent change in weight measured by a load cell.

FIG. 9 is an explanatory diagram showing a time-dependent change in weight measured by a load cell.

FIGS. 10A to 10C are explanatory diagrams showing how the wafer is transferred from the transfer arm to the wafer holder.

FIG. 11 is an explanatory diagram showing a time-dependent change in weight measured by a load cell.

FIG. 12 is an explanatory diagram showing how the wafer is transferred from the transfer arm to the wafer holder.

FIG. 13 is a perspective view showing an outline of a configuration of a wafer holder according to another embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of a semiconductor device, wafer processing such as an etching process is performed on a semiconductor wafer (substrate) (hereinafter referred to as a “wafer”) in a vacuum atmosphere. This wafer processing is performed using a wafer processing apparatus equipped with a plurality of processing modules.

For example, the wafer processing apparatus has a configuration in which a depressurized section kept in a vacuum atmosphere (depressurized atmosphere) and a normal pressure section kept in an atmospheric environment (normal pressure atmosphere) are connected integrally to each other via a load lock module.

The depressurized section includes a common transfer module and a plurality of processing modules connected to a periphery of the transfer module. The wafer is transferred from the transfer module kept in the vacuum atmosphere to the processing module where a desired processing is performed in the vacuum atmosphere.

The normal pressure section includes a load port on which a Front Opening Unified Pod (FOUP) capable of storing a plurality of wafers is placed, and a loader module equipped with a wafer transfer device. The wafer is transferred to the FOUP and the load lock module in the loader module kept in the atmospheric environment.

The load lock module is configured such that an interior thereof may be switched between the vacuum atmosphere and the atmospheric environment, and is configured to transfer the wafer between the depressurized section and the normal pressure section.

In the loader module, for example, as disclosed in Patent Document 1, the wafer transfer device for transferring the wafer in the atmospheric environment transfers the wafer by vacuum-suctioning the wafer using, for example, a plurality of pads provided on a hand (transfer arm). When delivering the wafer from the wafer transfer device to another module, the vacuum-suction by the pads is released such that the wafer is separated from the pads.

However, even if the vacuum-suction by the pads is released, the wafer may not be separated from the pads. This is due to, for example, the stickiness of the wafer. However, the pads in the related art do not anticipate such a separation difficulty. When the wafer is less likely to be separated from the pads, there may occur troubles such as the wafer jumping off the transfer arm during the delivery of the wafer, or the wafer remaining on the transfer arm without being delivered.

In order to avoid such troubles, it is necessary to properly evaluate separatability of the wafer from the pads. However, in the related art, the difficulty of wafer separation as described above is not assumed, and therefore the separatability of the wafer is also not evaluated.

The technique disclosed herein appropriately evaluates the separatability of the substrate for the transfer arm which holds and transfers the substrate. Hereinafter, the wafer processing apparatus according to the present embodiment will be described with reference to the drawings. In this specification and the drawings, elements having substantially the same functional configurations will be denoted by the same reference numerals, and duplicated descriptions thereof will be omitted.

### Wafer Processing Apparatus

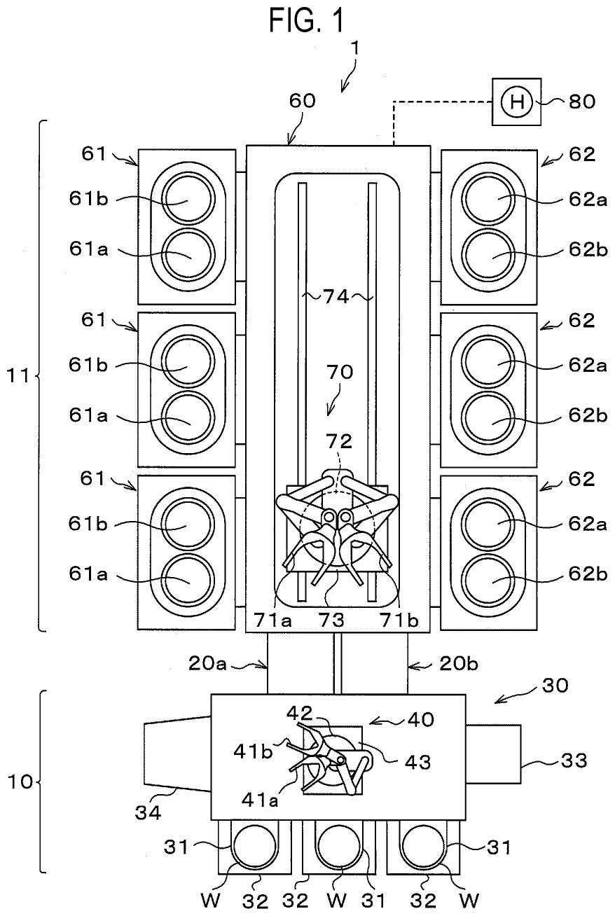

First, the wafer processing apparatus according to the present embodiment will be described. FIG. 1 is a plan view showing an outline of a configuration of a wafer processing apparatus 1. In the present embodiment, a case in which the wafer processing apparatus 1 includes various processing modules for performing a COR (Chemical Oxide Removal) process, a PHT (Post Heat Treatment) process, and a CST (Cooling Storage) process on the wafer W as a substrate, will be described. Configurations of the various processing modules provided in the wafer processing apparatus 1 according to the present disclosure are not limited thereto but may be arbitrarily selected.

As shown in FIG. 1, the wafer processing apparatus 1 has a configuration in which a normal pressure section 10 and a depressurized section 11 are connected integrally to each other via load lock modules 20a and 20b.

The load lock module 20a temporarily holds the wafer W transferred from a loader module 30 (to be described later) of the normal pressure section 10 to deliver the wafer W to a transfer module 60 (to be described later) of the depressurized section 11. The load lock module 20a simultaneously holds a plurality of wafers W, for example, two wafers W, in interiors thereof therein.

The load lock module 20a is connected to the loader module 30 and the transfer module 60 via gates (not shown) provided with gate valves (not shown). These gate valves ensure airtightness between the load lock module 20a and the loader module 30 and the transfer module 60 to be in communication with each other.

The load lock module 20a is connected to a gas supplier (not shown) for supplying a gas and an exhauster (not shown) for exhausting the gas, and is configured to have the interior capable of being switched between the atmospheric environment (normal pressure atmosphere) and the vacuum atmosphere (depressurized atmosphere) by the gas supplier and the exhauster. In other words, the load lock module 20a is configured such that the wafer W may be appropriately delivered between the normal pressure section 10 kept in the atmospheric environment and the depressurized section 11 kept in the vacuum atmosphere.

The load lock module 20b temporarily holds the wafer W transferred from the transfer module 60 to deliver the wafer W to the loader module 30. The load lock module 20b is similar in configuration to the load lock module 20a. That is, the load lock module 20b includes gate valves (not shown), gates (not shown), a gas supplier (not shown), and an exhauster (not shown).

The number and arrangement of the load lock modules 20a and 20b are not limited to those described in the present embodiment, but may be arbitrarily set.

The normal pressure section 10 includes a loader module 30 equipped with a wafer transfer device 40 described later, a load port 32 on which a FOUP 31 capable of storing the plurality of wafers W is placed, a CST module 33 for cooling the wafer W, and an aligner module 34 for adjusting a horizontal orientation of the wafer W.

The loader module 30 includes a rectangular housing whose interior is in the atmospheric environment. A plurality of (for example, three) load ports 32 is arranged side by side on one side constituting a long side of the housing of the loader module 30. The load lock modules 20a and 20b are arranged side by side on the other side constituting the long side of the housing of the loader module 30. The CST module 33 is provided on one side constituting a short side of the housing of the loader module 30. The aligner module 34 is provided on the other side constituting the short side of the housing of the loader module 30.

The numbers and arrangement of the load ports 32, the CST module 33, and the aligner module 34 are not limited to those described in the present embodiment, and may be arbitrarily set. In addition, the types of modules provided in the normal pressure section 10 are not limited to those described in the present embodiment, and may be arbitrarily selected.

The FOUP 31 accommodates the plurality of wafers, for example, one lot of 25 wafers W. The interior of the FOUP 31 placed on the load port 32 is filled with, for example, air or a nitrogen gas, and is sealed.

The CST module 33 holds a plurality of wafers W, for example, 35 wafers W more than the number of wafers that may be accommodated in the FOUP 31, in multiple stages at equal intervals in the wafer holder 200 (to be described later). A cooling process is performed on the plurality of wafers W held by the wafer holder 200. A configuration of the wafer holder 200 will be described later.

The aligner module 34 adjusts the horizontal orientation of the wafer W by rotating the wafer W. Specifically, when performing the wafer processing on each of the wafers W, the aligner module 34 adjusts the horizontal orientation of each wafer W with respect to a reference position (e.g., notch position) such that the horizontal orientations of the wafers W are identical to each other for each wafer processing.

The wafer transfer device 40 for transferring the wafer W is provided in the interior of the loader module 30. The wafer transfer device 40 includes transfer arms 41a and 41b which hold and move the wafer W, a rotary table 42 which rotatably supports the transfer arms 41a and 41b, and a rotational stage 43 on which the rotary table 42 is placed. A lifting mechanism (not shown) is provided inside the rotary table 42. The transfer arms 41a and 41b may be raised and lowered by the lifting mechanism. The wafer transfer device 40 is configured to be movable in a longitudinal direction in the interior of the housing of the loader module 30.

The depressurized section 11 includes a transfer module 60 which simultaneously transfers two wafers W, a COR module 61 which performs the COR process on the wafers W, and a PHT module 62 which performs the PHT process on the wafers W. Each of interiors of the transfer module 60, the COR module 61, and the PHT module 62A is kept in the vacuum atmosphere. A plurality of (for example, three) COR modules 61 and a plurality of (for example, three) PHT modules 62 are provided for the transfer module 60.

The transfer module 60 includes a housing whose interior is rectangular, and is connected to the load lock modules 20a and 20b via gate valves (not shown) as described above. The transfer module 60 sequentially transfers the wafer W loaded into the load lock module 20a to one COR module 61 and one PHT module 62 where the wafer W is subjected to the COR process and the PHT process. Thereafter, the transfer module 60 transfers the wafer W to the normal pressure section 10 via the load lock module 20b.

Two stages 61a and 61b on which two wafers W are placed side by side in the horizontal direction are provided inside the COR module 61. The COR module 61 simultaneously performs the COR process on the two wafers W by placing the wafers W side by side on the stages 61a and 61b. The COR module 61 is connected to a gas supplier (not shown) for supplying a processing gas, a purge gas or the like, and an exhauster (not shown) for discharging the gas.

Two stages 62a and 62b on which two wafers W are placed side by side in the horizontal direction are provided inside the PHT module 62. The PHT module 62 simultaneously performs the PHT process on the two wafers W by placing the wafers W side by side on the stages 62a and 62b. The PHT module 62 is connected to a gas supplier (not shown) for supplying a gas and an exhauster (not shown) for discharging the gas.

The COR module 61 and the PHT module 62 are connected to the transfer module 60 via gates (not shown) provided with gate valves (not shown). These gate valves ensure airtightness between the transfer module 60 and the COR module 61 and the PHT module 62 to be in communication with each other.

The number, arrangement, and type of the processing modules provided in the transfer module 60 are not limited to those described in the present embodiment, and may be arbitrarily set.

A wafer transfer device 70 is provided inside the transfer module 60 to transfer the wafer W. The wafer transfer device 70 includes transfer arms 71a and 71b for holding and moving two wafers W, a rotary table 72 for rotatably supporting the transfer arms 71a and 71b, and a rotational stage 73 on which the rotary table 72 is placed. A lifting mechanism (not shown) is provided inside the rotary table 72. The transfer arms 71a and 71b are configured to be raised and lowered by the lifting mechanism. A guide rail 74 is provided inside the transfer module 60 to extend in the longitudinal direction of the transfer module 60. The rotational stage 73 is provided on the guide rail 74. The wafer transfer device 70 is configured to move along the guide rail 74.

The above-described wafer processing apparatus 1 is provided with a controller 80. The controller 80 is, for example, a computer equipped with a CPU, a memory, and the like, and includes a program storage (not shown). The program storage stores a program for controlling the processing of the wafer W performed by the wafer processing apparatus 1. The program may be recorded in a computer-readable storage medium H and may be installed in the controller 80 from the storage medium H. The storage medium H may be transitory or non-transitory.

In the wafer processing apparatus 1 configured as above, first, the wafer W is transferred from the FOUP 31 to the aligner module 34 by the wafer transfer device 40 kept in the atmospheric environment to adjust the horizontal orientation of the wafer W. Subsequently, the wafer W is transferred to the load lock module 20a by the wafer transfer device 40.

Subsequently, the wafer W is transferred by the wafer transfer device 70 to the COR module 61 kept in the vacuum atmosphere where the wafer W is subjected to the COR process. Subsequently, the wafer W is transferred by the wafer transfer device 70 to the PHT module 62 where the wafer W is subjected to the PHT process. Subsequently, the wafer W is transferred by the wafer transfer device 70 to the load lock module 20b.

Subsequently, the wafer W is transferred by the wafer transfer device 40 to the CST module 33 kept in the atmospheric environment where the wafer W is subjected to the CST process. Subsequently, the wafer W is transferred by the wafer transfer device 40 to the FOUP 31. In this manner, a series of wafer processing performed in the wafer processing apparatus 1 ends.

### Transfer Arm

Next, the transfer arms 41a and 41b of the wafer transfer device 40 will be described. The transfer arms 41a and 41b have the same configuration, and will be collectively referred to as a transfer arm 41 below. The transfer arm 41 transfers the wafer W in a vacuum-suction manner.

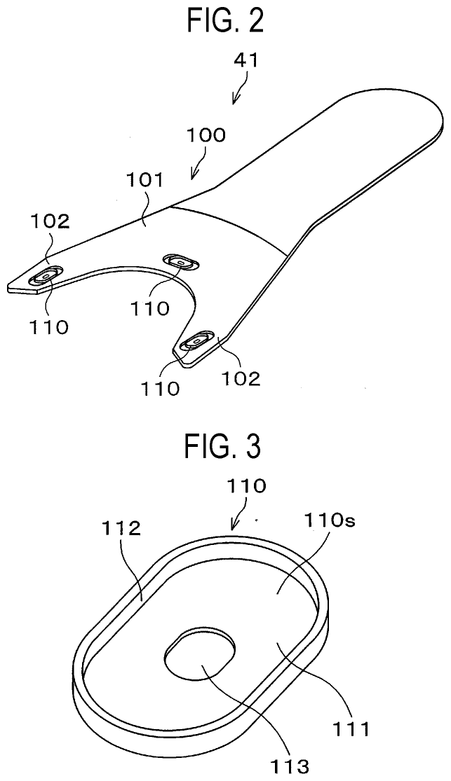

As shown in FIG. 2, the transfer arm 41 includes a pick 100 for holding the wafer W, and a plurality of (for example, three) holding pads 110 provided on a surface of the pick 100. The pick 100 has a fork shape branching from a base end 101 to two tip ends 102 and 102. The three holding pads 110 are provided on surfaces of the base end 101 and the tip ends 102 and 102, respectively.

As shown in FIG. 3, the holding pad 110 includes a base portion 111 provided on a bottom surface of the holding pad 110, and an annular portion 112 provided in a circular ring shape on a surface of the base portion 111. The annular portion 112 has, for example, an oval shape in a plan view. A through-hole 113 for vacuum-suction is formed in the base portion 111. A gas supplier (not shown) for supplying a gas to the interior of the holding pad 110, and an exhauster (not shown) for suctioning the gas from the interior of the holding pad 110 to evacuate the interior of the holding pad 110 are connected to the through-hole 113.

In order to hold the wafer W by the holding pad 110, an adsorption space 110s formed by a back surface of the wafer W, the base portion 111 and the annular portion 112 is evacuated in a state in which the annular portion 112 is in contact with the back surface of the wafer W. On the other hand, in order to separate the wafer W from the holding pad 110, the evacuation of the adsorption space 110s is stopped, and the gas is further supplied to the adsorption space 110s. Then, the wafer W is relatively raised from the holding pad 110 to be delivered to a transfer destination.

The configuration of the holding pad 110 is not limited to that described in the present embodiment. For example, a planar shape of the holding pad 110 may be any shape other than an ellipse shape.

### Wafer Holder

Next, the wafer holder 200, which is a substrate holder provided in the CST module 33 as a substrate processing apparatus, will be described. The wafer holder 200 holds the plurality of wafers W at equal intervals in multiple stages. Then, inside the processing container (not shown) of the CST module 33, a fan (not shown) is operated to introduce air having room temperature to cool the wafers W in a state in which the wafers W are held by the wafer holder 200.

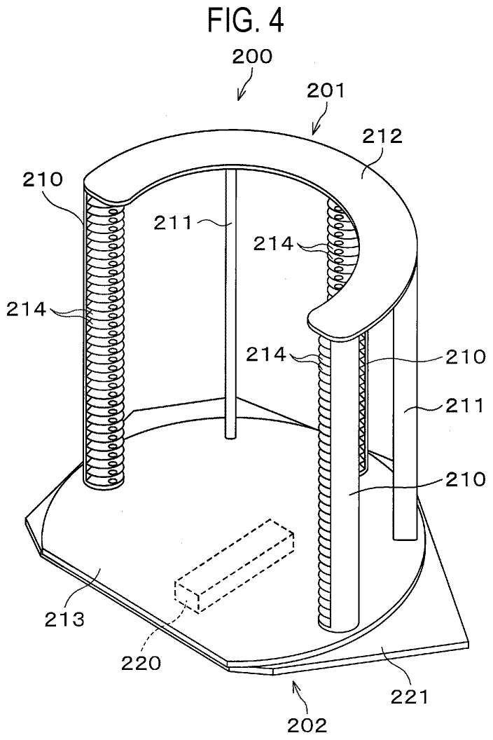

As shown in FIG. 4, the wafer holder 200 includes a wafer storage 201 as a stage and a force gauge 202. The wafer storage 201 holds the plurality of wafers W in multiple stages. A horizontal center of gravity of the wafer storage 201 is designed to coincide with the center of the wafer W. The force gauge 202 measures a weight of the wafer storage 201. There are various types of force gauges 202, which are force measuring instruments. The force gauge 202 shown in FIG. 4 is equipped with a beam-type load cell 220, which will be described later.

The wafer storage 201 includes wafer holding columns 210, auxiliary columns 211, a top plate 212, and a bottom plate 213. The wafer storage 201 is supported by a load cell 220 (to be described later) and is configured to be movable up and down in the vertical direction and movable in the horizontal direction. In other words, the wafer storage 201 is not supported by other members other than the load cell 220. The auxiliary columns 211 are not essential and may be provided as necessary.

A plurality of (for example, three) wafer holding columns 210 are provided. For example, two auxiliary columns 211 are provided between the three wafer holding columns 210. The three wafer holding columns 210 and the two auxiliary columns 211 are arranged at equal intervals on a semicircle with the same center. The top plate 212 supports upper ends of the wafer holding columns 210 and upper ends of the auxiliary columns 211. The top plate 212 of the present embodiment has a substantially arc shape in a plan view, but the planar shape of the top plate 212 is not limited thereto. The bottom plate 213 supports lower ends of the wafer holding columns 210 and lower ends of the auxiliary columns 211. The bottom plate 213 of the present embodiment has a substantially circular shape with a notch formed in a plan view, but the planar shape of the bottom plate 213 is not limited thereto.

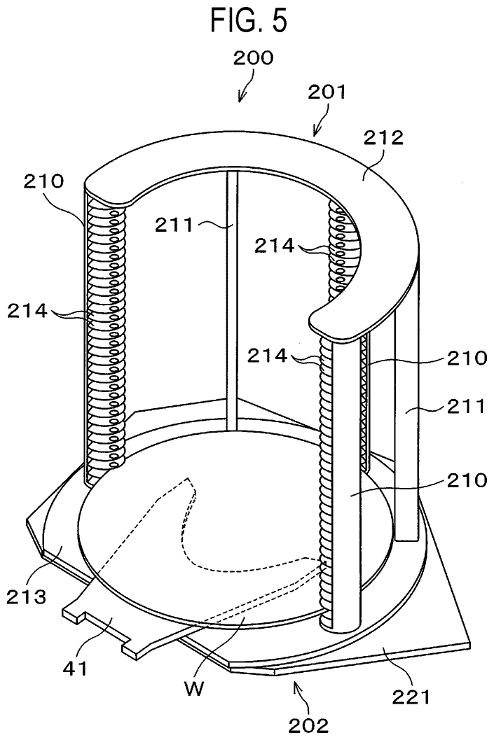

A plurality of placement members 214 is provided in the wafer holding column 210 at equal intervals in the vertical direction. The placement members 214 protrude radially inward from the wafer holding column 210. In addition, in the three wafer holding columns 210, the corresponding placement members 214 are disposed at the same height. As shown in FIG. 5, each placement member 214 places the outer periphery of the wafer W thereon so that the wafer W is held horizontally in the wafer storage 201. The number of wafer holding columns 210 is not limited to that described in the present embodiment, but at least three or more wafer holding columns 210 are necessary to hold the wafers W horizontally.

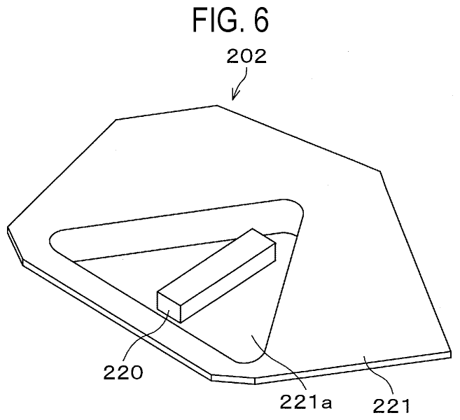

As shown in FIG. 6, the force gauge 202 includes a load cell 220 as a measurer, and a support plate 221. In order to explain an internal structure of the force gauge 202, the wafer storage 201 is not shown FIG. 6.

The load cell 220 supports the bottom plate 213 of the wafer storage 201 and measures a vertical weight of the wafer storage 201. An installation position of the load cell 220 is designed so as to receive a vertical force at the horizontal center of gravity of the wafer storage 201. A configuration of the load cell 220 is not particularly limited. A load cell that meets conditions of use may be used.

The load cell 220 is provided in a recess 221a formed at the center of the support plate 221. The load cell 220 is provided so as to protrude from the upper surface of the support plate 221. In this configuration, a gap is formed between the lower surface of the bottom plate 213 and the upper surface of the support plate 221, and the wafer storage 201 supported by the load cell 220 is configured to be capable of being raised and lowered in the vertical direction. The support plate 221 is fixed to a processing container (not shown) of the CST module 33.

In the present embodiment, one load cell 220 is provided, but the number of load cells 220 is not limited thereto. Since the wafer storage 201 is supported by the load cell 220, for example, in a case in which a plurality of load cells 220 are provided, a rigidity required for supporting the wafer storage 201 is increased. In such a case, measurement results obtained by the plurality of load cells 220 are combined to each with to measure the weight of the wafer storage 201.

### Wafer Transfer Method

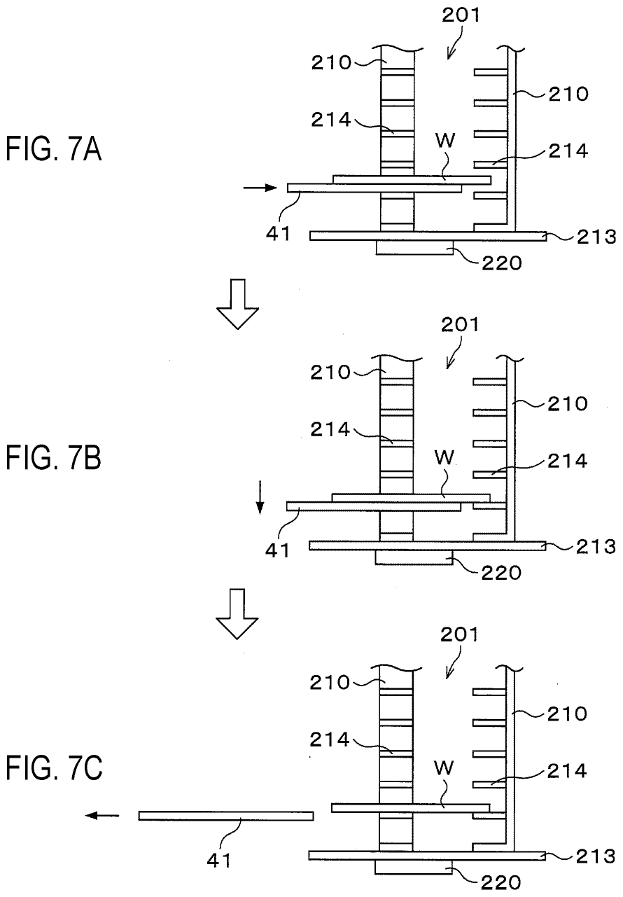

Next, a method of transferring the wafer W from the transfer arm 41 of the wafer transfer device 40 to the wafer holder 200 of the CST module 33 and allowing the wafer holder 200 to hold the wafer W will be described. FIG. 7 is an explanatory diagram showing a state in which the wafer W is transferred from the transfer arm 41 to the wafer holder 200.

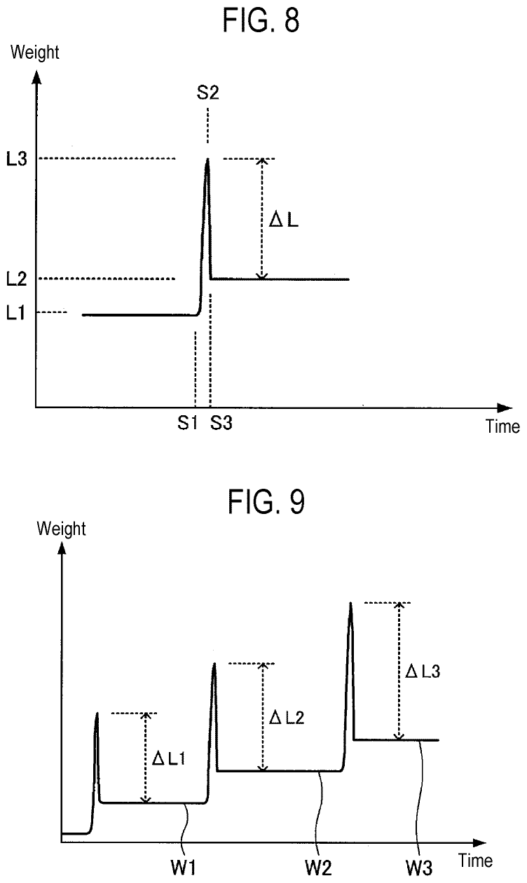

Further, while the wafer W is being transferred from the transfer arm 41 to the wafer holder 200, the load cell 220 constantly measures the weight of the wafer storage 201. Wight data measured by the load cell 220 is output to the controller 80. FIG. 8 is an explanatory diagram showing a time-dependent change in the weight measured by the load cell 220. In FIG. 8, the vertical axis indicates the weight, and the horizontal axis indicates the time.

First, as shown in FIG. 7A, the transfer arm 41 which holds the wafer W in a vacuum-suction manner advances toward the wafer storage 201 (step S1). The wafer W advances between the placement members 214 adjacent to each other in the vertical direction. At this time, as shown in FIG. 8, the weight of the wafer storage 201 is weight L1 not including the weight of the wafer W.

Subsequently, the evacuation of the adsorption space 110s formed between the holding pad 110 of the transfer arm 41 and the wafer W is stopped, and a gas is further supplied to the adsorption space 110s. Then, the suction-holding of the wafer W by the transfer arm 41 is stopped.

Subsequently, as shown in FIG. 7B, the transfer arm 41 is lowered, and the wafer W is delivered from the transfer arm 41 to the wafer storage 201 and placed on the placement members 214 (step S2).

When the wafer W is held by the wafer storage 201, the weight of the wafer storage 201 becomes weight L2, which is obtained by adding the weight of the wafer W to weight L1. In this regard, in step S2, even if the evacuation of the adsorption space 110s is stopped as described above, the wafer W is less likely to be separated from the holding pad 110. That is, since the wafer W has stickiness and the wafer W and the holding pad 110 adhere to each other, the wafer W is hardly separated from the holding pad 110. Then, when the wafer W is placed on the placement members 214, a downward load acts on the wafer storage 201 so that the wafer storage 201 is lowered. In addition, when the wafer W is lowered and placed on the placement members 214, impact may be generated. Even by such an impact, a downward load may act on the wafer storage 201. As a result, as shown in FIG. 8, the load cell 220 measures weight L3, which is greater than weight L2.

Subsequently, as shown in FIG. 7C, the transfer arm 41 is retreated from the wafer storage 201 (step S3). At this time, as shown in FIG. 8, the weight measured by the load cell 220 becomes weight L2 obtained by adding the weight of the wafer W to weight L1 of the wafer storage 201.

When the wafer W is transferred from the transfer arm 41 to the wafer holder 200 as described above, the controller 80 monitors the weight measured by the load cell 220 shown in FIG. 8. Then, based on a weight difference ΔL (=L3−L2) between weights L3 and L2, a separatability of the wafer W from the holding pad 110 is evaluated. That is, when the weight difference ΔL is large, it indicates that the wafer W is hardly to be separated, and when the weight difference ΔL is small, it indicates that the wafer W is likely to be separated.

As described above, the stickiness of the wafer W makes it difficult to separate the wafer W from the holding pad 110. When the holding pad 110 deteriorates, the separatability of the wafer W deteriorates. Therefore, the controller 80 predicts a state of the holding pad 110 (a state of the transfer arm 41) based on the weight difference ΔL. Then, when the weight difference ΔL exceeds a predetermined threshold value, an alarm is output from an outputer (not shown) of the wafer processing apparatus 1.

The threshold value of the weight difference AL when the alarm is output may be arbitrarily set. For example, as described above, when the separatability of the wafer W deteriorates, the wafer W may jump off the transfer arm 41. The threshold value may be set to prevent such jumping. Alternatively, the threshold value may be set at the time of replacing the holding pad 110.

According to the above-described embodiment, the wafer holder 200 includes the force gauge 202. Therefore, it is possible to constantly monitor the weight of the wafer storage 201. Further, based on the time-dependent change in the weight of the wafer storage 201, it is possible to evaluate the separatability of the wafer W from the holding pad 110 in a digitization manner.

Specifically, for example, when three wafers W are transferred from the transfer arm 41 to the wafer holder 200 as shown in FIG. 9, the weight measured by the load cell 220 increases stepwise. Here, it is assumed that a first wafer W1 is not adhered to the holding pad 110 and has a “large” separatability, a second wafer W2 is slightly adhered to the holding pad 110 and has a “medium” separatability, and a third wafer W3 is considerably adhered to the holding pad 110 and has a “small” separatability. In this case, the weight difference ΔL1 when the first wafer W1 is placed, the weight difference ΔL2 when the second wafer W2 is placed, and the weight difference ΔL3 when the third wafer W3 is placed increase in the named order (ΔL1<ΔL2<ΔL3). Therefore, the separatability of the wafer W from the holding pad 110 may be evaluated in the digitization manner.

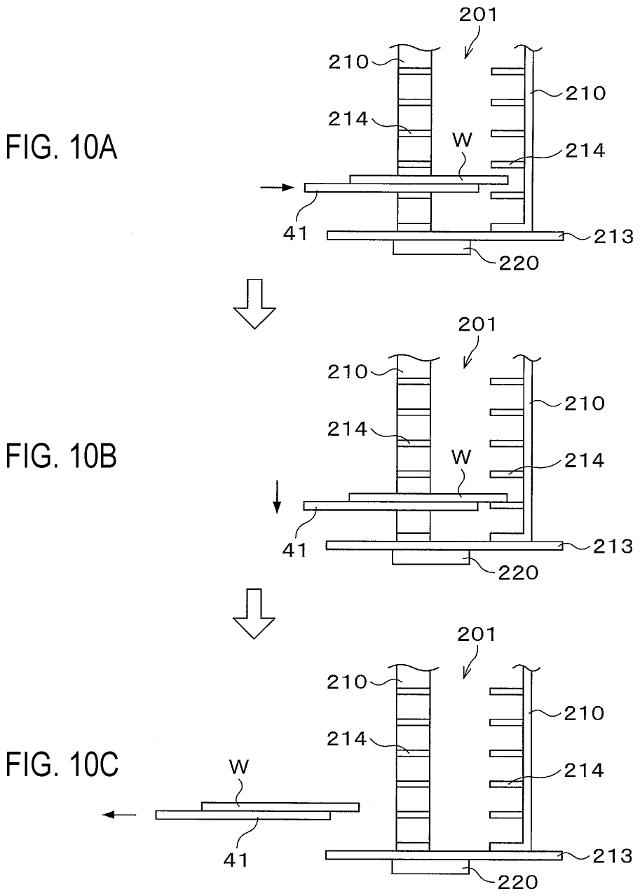

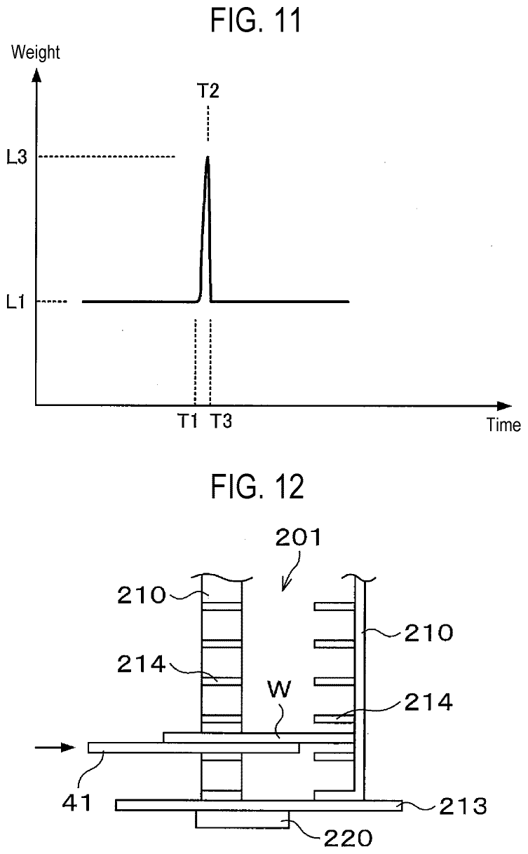

In the above-described embodiment, when the separatability of the wafer W from the holding pad 110 further deteriorates, the wafer W may not be delivered from the transfer arm 41 to the wafer storage 201. FIG. 10 is an explanatory diagram showing a state in which the wafer W is transferred from the transfer arm 41 to the wafer holder 200 in the present embodiment. FIG. 11 is an explanatory diagram showing a time-dependent change in the weight measured by the load cell 220 in the present embodiment.

First, as shown in FIG. 10A, the transfer arm 41 which holds the wafer W in a vacuum-suction manner advances toward the wafer storage 201 (step T1). Step T1 is the same as step S1 in the above-described embodiment. As shown in FIG. 11, the weight of the wafer storage 201 is weight L1.

Subsequently, after the evacuation of the adsorption space 110s is stopped, as shown in FIG. 10B, the transfer arm 41 is lowered, and the wafer W is delivered from the transfer arm 41 to the wafer storage 201 and placed on the placement member 214 (step T2). Step T2 is the same as step S2 in the above-described embodiment. As shown in FIG. 11, the weight of the wafer storage 201 is weight L3.

Subsequently, as shown in FIG. 10C, the transfer arm 41 is retreated from the wafer storage 201 (step T3). At this time, in the present embodiment, the transfer arm 41 is retreated together with the wafer W without placing the wafer W on the placement members 214 because the wafer W has low separatability. Then, as shown in FIG. 11, the weight of the wafer storage 201 becomes weight L1 not including the weight of the wafer W.

As described above, in the present embodiment as well, when the wafer W is transferred from the transfer arm 41 to the wafer holder 200, the controller 80 monitors the weight measured by the load cell 220 shown in FIG. 11. Then, when the weight after the transfer arm 41 is retreated is weight L1, it may represent that the transfer arm 41 has been retreated in a state in which the wafer W is left on the transfer arm 41. Therefore, the separatability of the wafer W from the holding pad 110 may be evaluated in a digitization manner.

Further, when the weight after the transfer arm 41 is retreated is weight L1, the controller 80 controls the outputer (not shown) of the wafer processing apparatus 1 to output an alarm (or warning). In the present embodiment, when the separatability of the wafer W deteriorates to such an extent that the wafer W cannot be delivered from the transfer arm 41 to the wafer storage 201, the holding pad 110 needs to be replaced. To do this, the alarm is output to notify the replacement of the holding pad 110. The alarm in the present embodiment (FIG. 11) may be different from the alarm in the above-described embodiment (FIG. 8) such that they are distinguished from each other.

In the wafer holder 200 of the above-described embodiment, when the transfer arm 41 which suction-holds the wafer W advances toward the wafer storage 201 in steps S1 and T1, the misalignment of the wafer W on the transfer arm 41 may also be detected.

For example, as shown in FIG. 12, the position of the wafer W may be shifted in a traveling direction with respect to the transfer arm 41. In such a case, when the transfer arm 41 advances toward the wafer storage 201, the wafer W collides with the wafer holding column 210 before the transfer arm 41 reaches a predetermined position. As a result, a moment load acts on the wafer holding column 210 so that the weight measured by the load cell 220 is increased. Specifically, as described above, the weight measured by the load cell 220 is increased at a timing earlier than the weight L3 at the time of placing the wafer W. The controller 80 detects the collision of the wafer W based on the increase in weight, and further detects that the position of the wafer W is shifted on the transfer arm 41.

### Other Embodiments

In the above-described embodiments, the load cell 220 which measures the weight of the wafer storage 201 is used as the measurer. However, a target to be measured by the measurer is not limited thereto.

For example, the measurer may be a pressure sensor configured to measure a pressure acting vertically downward from the wafer storage 201. In this case, a pressure gauge equipped with such a pressure sensor (not shown) is provided below the wafer storage 201 instead of the force gauge 202. A change in pressure of the wafer storage 201 exhibits the same behavior as the change in the weight of the wafer storage 201 described above. Thus, the separatability of the wafer W from the holding pad 110 may be evaluated in a digitization manner based on a time-dependent change in the pressure of the wafer storage 201, which is measured by the pressure sensor.

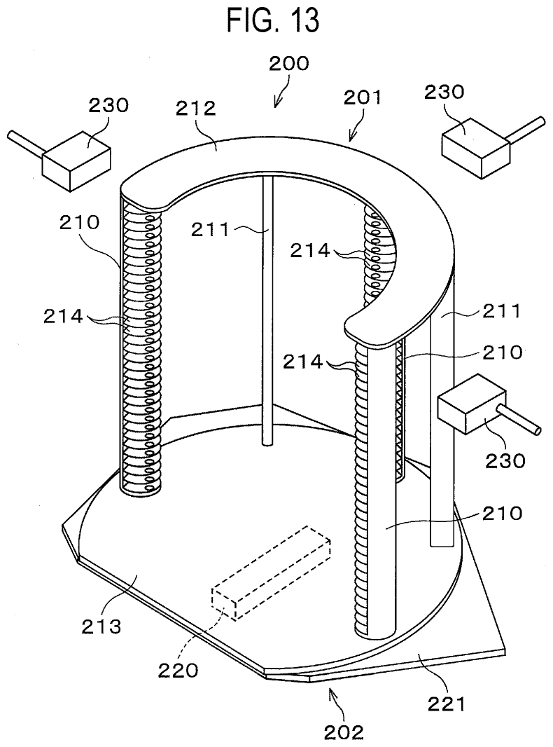

In addition, for example, a laser displacement meter configured to measure a vertical displacement of the wafer storage 201 may be used as the measurer. As shown in FIG. 13, a plurality of (for example, three) laser displacement meters 230 is provided so as to correspond to the three wafer holding columns 210. When the wafer W is placed on the placement members 214, a downward load acts on the wafer storage 201 so that the wafer storage 201 is lowered. As a result, based on a time-dependent change in the vertical displacement of the wafer holding columns 210, which is measured by the laser displacement meter 230, the separatability of the wafer W from the holding pad 110 may be evaluated in a digitization manner.

In the above-described embodiment, in steps S2 and T2, the transfer arm 41 is lowered and the wafer W is delivered from the transfer arm 41 to the wafer storage 201. Alternatively, the wafer storage 201 may be raised by a lifting mechanism (not shown). In addition, the transfer arm 41 may be lowered and the wafer storage 201 may be raised at the same time. The wafer W may be delivered from the transfer arm 41 to the wafer storage 201 by moving the transfer arm 41 and the wafer storage 201 relative to each other in the vertical direction.

In the above-described embodiment, the weight data measured by the load cell 220 is output to the controller 80 provided in the wafer processing apparatus 1. Alternatively, the weight data may be output to, for example, a separate controller (not shown). In such a case, a controller for the wafer holder 200 may be provided.

In the above-described embodiment, the wafer holder 200 is provided inside the CST module 33, but a target to which wafer holder 200 is installed is not limited thereto.

For example, the wafer holder 200 may be provided inside the aligner module 34 serving as a substrate processing apparatus. In such a case, the wafer holder 200 is configured to hold one wafer W. Further, based on the time-dependent change in the weight or the like of the wafer storage 201, the separatability of the wafer W from the holding pad 110 may be evaluated in a digitization manner.

In addition, for example, the wafer holder 200 may be provided inside the load lock module 20a or 20b serving as a substrate processing apparatus. In such a case, the wafer holder 200 is configured to hold two wafers W. In the following description, an example in which the wafer holder 200 is provided in the load lock module 20a will be described. The same applies when the wafer holder 200 is provided in the load lock module 20b.

The transfer arms 41a and 41b (first transfer arms in the present disclosure) of the wafer transfer device 40 and the transfer arms 71a and 71b (second transfer arms in the present disclosure) of the wafer transfer device 70 access to the load lock module 20a. Hereinafter, the transfer arms 41a and 41b are collectively referred to as a transfer arm 41, and the transfer arms 71a and 71b are collectively referred to as a transfer arm 71.

When the wafer W is transferred from the transfer arm 41 to the wafer holder 200, the separatability of the wafer W from the holding pad 110 may be evaluated in a digitization manner based on the time-dependent change in the weight or the like of the wafer storage 201.

In addition, when the wafer W is transferred from the transfer arm 71 to the wafer holder 200, the separatability of the wafer W from the holding pad (not shown) of the transfer arm 71 may be evaluated in a digitization manner based on the time-dependent change in the weight or the like of the wafer storage 201.

Here, the transfer arm 41 suction-holds the wafer W by evacuation, whereas the transfer arm 71 holds the wafer W by virtue of a frictional force. Like the transfer arm 41 shown in FIGS. 2 and 3, the transfer arm 71 includes a pick 100 with a base end 101 and a tip end 102, and holding pads (not shown) provided on a surface of the pick 100. Unlike the holding pads 110 of the transfer arm 41, the holding pads of the transfer arm 71 hold the wafer W by virtue of the frictional force.

The holding pads of the transfer arm 71 may be made of a material having low stickiness with respect to the wafer W. In this case, the separatability of the wafer W from the holding pads may be increased. Further, a material that exerts a large frictional force may be used as the holding pads as long as the weight of the wafer storage 201 may be measured as in the wafer holder 200 of the present embodiment and the wafer W can be separated. This improves a degree of freedom of selection of the material for the holding pads.

In addition, for example, the wafer holder 200 may be applied to the wafer transfer device 40 (or 70) to measure the weight or the like of the wafer W held by the transfer arm 41 (or 71).

According to the present disclosure in some embodiments, it is possible to appropriately evaluate a separatability of a substrate when a transfer arm holds and transfers the substrate.

The embodiments disclosed herein should be considered as exemplary and not limitative in all respects. The above-described embodiments may be omitted, substituted, or modified in various forms without departing from the scope and spirit of the appended claims.

What is claimed is:

1. A substrate holder for receiving a substrate from a transfer arm and holding the substrate, comprising:
a stage configured to be raised and lowered in a vertical direction and configured to place the substrate thereon;
a measurer configured to measure at least one of a weight, a pressure, and a displacement of the stage; and
a controller configured to predict a state of the transfer arm based on measurement results of the measurer.

2. The substrate holder of claim 1, wherein the measurer is configured to support the stage and measure the weight of the stage.

3. The substrate holder of claim 2, wherein the transfer arm includes a plurality of holding pads configured to hold the substrate, and
wherein the controller is configured to predict a state of the plurality of holding pads based on a change in the weight measured by the measurer when the substrate is placed on the stage from the transfer arm.

4. The substrate holder of claim 2, wherein the transfer arm includes a plurality of holding pads configured to hold the substrate, and
wherein the controller is configured to predict a state of the plurality of holding pads based on a change in the weight measured by the measurer when the transfer arm is retreated from the stage.

5. The substrate holder of claim 2, wherein the controller is configured to predict a state of the substrate on the transfer arm based on a change in the weight measured by the measurer when the transfer arm advances to the stage.

6. The substrate holder of claim 3, wherein the controller is configured to output an alarm when the change in the weight exceeds a threshold value.

7. The substrate holder of claim 2, wherein the stage includes:
a plurality of support columns;
placement members provided on the plurality of support columns and configured to place an outer periphery of the substrate thereon; and
a bottom plate configured to support lower ends of the plurality of support columns, and
wherein the measurer is configured to support the bottom plate.

8. A substrate processing apparatus, comprising:
the substrate holder of claim 1,
wherein the transfer arm is configured to suction-hold and transfer the substrate in an atmospheric environment, and
wherein the substrate processing apparatus is configured to process the substrate held by the substrate holder in the atmospheric environment.

9. A substrate processing apparatus, comprising:
the substrate holder of claim 1,
wherein the transfer arm includes a first transfer arm and a second transfer arm,
wherein the first transfer arm is configured to suction-hold and transfer the substrate in an atmospheric environment,
wherein the second transfer arm is configured to hold and transfer the substrate in a vacuum atmosphere, and
wherein the substrate processing apparatus is configured to be switchable between the atmospheric environment and the vacuum atmosphere in a state in which the substrate is held by the substrate holder.

10. A substrate transfer method of transferring a substrate from a transfer arm to a substrate holder such that the substrate holder holds the substrate, the substrate transfer method comprising:
advancing the transfer arm for holding the substrate, toward a stage configured to be raised and lowered in a vertical direction in the substrate holder;
moving the transfer arm and the substrate holder relative to each other in the vertical direction to deliver the substrate from the transfer arm to the stage;
measuring, by a measurer of the substrate holder, at least one of a weight, a pressure, and a displacement of the stage; and
predicting a state of the transfer arm based on measurement results of the measurer.
